(19) United States
(12) Patent Application Publication
(10) Pub. No.: US 2007/0141476 A1
(43) Pub. Date: Jun. 21, 2007

(54) More accurate and physical method to account for lithographic and etch contributions in OPC models

(75) Inventors: Lewis W. Flanagin, Richardson, TX (US); Mark E. Mason, Allen, TX (US)

Correspondence Address: TEXAS INSTRUMENTS INCORPORATED, P O BOX 655474, M/S 3999, DALLAS, TX, 75265, US

(73) Assignee: Texas Instruments Incorporated

(21) Appl. No.: 11/304,656

(22) Filed: Dec. 16, 2005

(51) Int. Cl. G03F 1/00; G06F 17/50

(52) U.S. Cl. 430/5; 716/19

(57) ABSTRACT

A method for manufacturing a corrected photo mask using an optical proximity effect correction method, the method comprising of the steps of: producing a test mask that provides a mask pattern for extracting a plurality of function models of a plurality of processes for the optical proximity effect correction method; transferring the mask pattern to a wafer by executing the plurality of processes, wherein each one of the plurality of processes forms a resulting pattern on the wafer; measuring the dimensions of the resulting pattern on the wafer after each one of the plurality of processes is executed; obtaining a function model for each one of the plurality of processes executed in which the dimensions of a simulated resulting pattern match the dimensions of the resulting pattern on the wafer after each one of the plurality of processes is executed; providing a photo mask design pattern; obtaining a mask pattern of which a simulated transferred pattern matches the photo mask design pattern by applying the function model for each one of the plurality of processes sequentially and creating mask data in accordance with the simulated transferred pattern; and producing a corrected photo mask in accordance with the created mask data.

### FIELD OF THE INVENTION

The subject matter of this invention relates to methods of improving semiconductor device manufacturing. More particularly, the subject matter of this invention relates to a method of improving OPC modeling.

### BACKGROUND OF THE INVENTION

Integrated circuit fabrication techniques typically use a mask to project patterns of electromagnetic radiation onto a layer of photoresist on a substrate. The electromagnetic radiation is typically of a wavelength in the ultra violet band, but may be from another portion of the spectrum. The density of the features defined by projecting the mask pattern onto the photoresist tends to be limited by various distorting characteristics of the mask, the radiation, and the photoresist.

However, the manufacturing process typically employs other processes in addition to lithographic projection. Prior to the imaging step, the substrate may undergo various procedures, such as: priming, resist coating, and a soft bake. After exposure, the substrate can be subjected to other procedures, such as a post-exposure bake (PEB), development, a hard bake, and a measurement/inspection of the image features. This array of procedures can be used as a basis to pattern an individual layer of a device, such as an IC. Such a patterned layer may then undergo various processes, such as etching, ion-implantation, doping, metallization, oxidation, chemical mechanical polishing (CMP), etc., all intended to complete an individual layer.

All of these processes used to form the final feature in a layer tend to alter the pattern as it was projected from the mask onto the substrate. As a result, mask patterns with critical dimensions smaller than the exposure wavelength typically result in distorted images of the original layout pattern. In addition, the nonlinear response of the photoresist to variability in exposure tool and mask manufacturing process as well as variability in resist and thin film processes also contribute to image distortion. These distortions include variations in the line-widths of identically drawn features in dense and isolated environments (iso-dense bias), line-end pullback or line-end shortening from drawn positions and corner rounding. Similarly, other processes also result in image distortion.

One of the goals in IC fabrication is to reproduce faithfully the original circuit design on the wafer using the mask. Another goal is to use as much of the wafer real estate as possible. Furthermore, the constant improvements in microprocessor speed, memory-packing density, and low power consumption for micro-electronic components can be directly related to the ability of lithographic techniques to transfer and form patterns onto the various layers of a semiconductor device. In order to keep pace with Moore's law and develop sub-wavelength resolution, it has become necessary to use a variety of resolution enhancement techniques (RET) to counteract the distortion of the original mask pattern.

Various RET techniques have been developed to counteract the effects of these distorting characteristics. One such technique, optical proximity correction (OPC), operates by adding distortion compensating patterns throughout the mask. OPC is a procedure of pre-distorting the mask layout by using simple shape manipulation rules (rule-based OPC) or fragmenting the original polygon into line segments and moving these segments to favorable positions as determined by a process model (model-based OPC). OPC improves image fidelity on a wafer.

As the semiconductor industry pushes to resolve smaller critical dimensions, the need to provide more accurate OPC modeling becomes critical. Some present models are based on experiment and observation. These empirical models are generated using top-down critical-dimension measurements or scanning electron microscope (SEM) images of the final feature dimensions. Other techniques have used models derived from first principles but have focused only on variations in the photoresist process and have ignored subsequent process contributions.

As stated above, the patterns projected onto the photoresist are subsequently used to mask an underlying layer during an etch step. Unfortunately, even an accurate correction for the photoresist process can still result in distorted patterns on the wafer. Similarly, a correction based on the final formed feature is still inaccurate. The cause is that additional distortions of the shape of the desired feature occur during the execution of each process step that occurs after formation of the photoresist pattern. Each additional distortion is independent and determined solely by the state of the wafer and the effects of the particular process step. This tends to further limit the feature density of the integrated circuit.

What is needed, therefore, is a system that accounts for the differences between a pattern on a mask and the resulting pattern in a layer, which is eventually produced by use of the mask, by accounting for the contribution of distortion from various process steps performed on the wafer.

### SUMMARY OF THE INVENTION

In accordance with the invention, there is a method for manufacturing a corrected photo mask using the improved and more accurate optical proximity effect correction method. The method first comprises producing a test mask that provides a mask pattern for extracting a plurality of function models of a plurality of processes for the optical proximity effect correction method. The method further comprises transferring the mask pattern to a wafer by executing the plurality of processes, wherein each one of the plurality of processes forms a resulting pattern on the wafer, and the dimensions of the resulting pattern on the wafer after each one of the plurality of processes are measured. The method further comprises obtaining a function model for each one of the plurality of processes executed, in which the dimensions of a simulated resulting pattern match the corresponding dimensions of the resulting pattern on the wafer after each one of the plurality of processes is executed. The method is further comprised of providing a photo mask design pattern, obtaining a mask pattern of which a simulated transferred pattern matches the photo mask design pattern by applying the function model for each one of the plurality of processes sequentially, and creating mask data in accordance with the simulated transferred pattern. Finally, a corrected photo mask is produced in accordance with the created mask data.

In accordance with the invention, there is also a method for manufacturing a semiconductor device using a corrected photo mask using an optical proximity effect correction method. The method comprises producing a test mask that provides a mask pattern for extracting a plurality of function models of a plurality of processes for applying the optical proximity effect correction method. The method further comprises transferring the mask pattern to a wafer by executing the plurality of processes, wherein each one of the plurality of processes forms a resulting pattern on the wafer and measuring the dimensions of the resulting pattern on the wafer after each one of the plurality of processes is executed. Furthermore, the method comprises obtaining a function model for each one of the plurality of processes executed in which the dimensions of a simulated resulting pattern match the dimensions of the resulting pattern on the wafer after each one of the plurality of processes is executed. The method is further comprised of providing a photo mask design pattern, obtaining a mask pattern of which a simulated transferred pattern matches the photo mask design pattern by applying the function model for each one of the plurality of processes sequentially and creating mask data in accordance with the simulated transferred pattern, and producing a corrected photo mask in accordance with the created mask data. Finally, a corrected mask pattern is transferred to a wafer by executing the plurality of processes, wherein each one of the plurality of processes forms a resulting corrected pattern on the wafer.

In accordance with the invention, there is also a method for obtaining an optical proximity effect correction model. The method comprises producing a test mask that provides a mask pattern for extracting a plurality of function models of a plurality of processes for obtaining the optical proximity effect correction model. The method further comprises transferring the mask pattern to a wafer by executing the plurality of processes, wherein each one of the plurality of processes forms a resulting pattern on the wafer and measuring the dimensions of the resulting pattern on the wafer after each one of the plurality of processes is executed. The method also comprises obtaining a function model for each one of the plurality of processes executed in which the dimensions of a simulated resulting pattern match the dimensions of the resulting pattern on the wafer after each one of the plurality of processes is executed.

There is also an integrated circuit device produced with a method in accordance with the invention. The method to form the integrated device comprises producing a test mask that provides a mask pattern for extracting a plurality of function models of a plurality of processes. The method further comprises transferring the mask pattern to a wafer by executing the plurality of processes, wherein each one of the plurality of processes forms a resulting pattern on the wafer and measuring the dimensions of the resulting pattern on the wafer after each one of the plurality of processes is executed. The method also comprises obtaining a function model for each one of the plurality of processes executed in which the dimensions of a simulated resulting pattern match the dimensions of the resulting pattern on the wafer after each one of the plurality of processes is executed. Furthermore, the method comprises providing a photo mask design pattern, obtaining a mask pattern of which a simulated transferred pattern matches the photo mask design pattern by applying the function model for each one of the plurality of processes sequentially and creating mask data in accordance with the simulated transferred pattern, and producing a corrected photo mask in accordance with the created mask data. Finally, the method comprises transferring a corrected mask pattern to a wafer by executing the plurality of processes sequentially, wherein each one of the plurality of processes forms a resulting corrected pattern on the wafer forming the integrated circuit device.

There is also a corrected photo mask formed in accordance with the invention. The method to form the corrected photo mask comprises producing a test mask that provides a mask pattern for extracting a plurality of function models of a plurality of processes. The method further comprises transferring the mask pattern to a wafer by executing the plurality of processes, wherein each one of the plurality of processes forms a resulting pattern on the wafer and measuring the dimensions of the resulting pattern on the wafer after each one of the plurality of processes is executed. The method also comprises obtaining a function model for each one of the plurality of processes executed in which the dimensions of a simulated resulting pattern match the dimensions of the resulting pattern on the wafer after each one of the plurality of processes is executed. Furthermore, the method also comprises providing a photo mask design pattern, obtaining a mask pattern of which a simulated transferred pattern matches the photo mask design pattern by applying the function model for each one of the plurality of processes sequentially and creating mask data in accordance with the simulated transferred pattern, and producing a corrected photo mask in accordance with the created mask data.

In accordance with the invention, there is also a computer readable medium containing program code that configures a processor to obtain a model for correcting a mask layout using an optical proximity correction method to account for a plurality of processes to be performed on a wafer. The program code on the medium would be comprised of program code for reading a test mask pattern comprising a plurality of pattern features for extracting a plurality of function models for a plurality of processes. The program code on the medium would further be comprised of program code for inputting the dimensions of the plurality of pattern features after each one of the plurality of processes is performed on the wafer and program code for extracting a function model for each one of the plurality of processes based on the inputted dimensions of the plurality of pattern features. Finally, the program code on the medium would also be comprised of program code for obtaining a correction model for each one of the plurality of processes, wherein the function model for each of the plurality of processes is used to extrapolate a pattern feature correction to achieve a desired feature dimension.

In accordance with the invention, there is also a computer readable medium containing program code that configures a processor to correct a mask layout using an optical proximity correction method that accounts for a plurality of processes to be performed on a wafer. The program code on the medium would be comprised of program code for reading a test mask pattern comprising a plurality of pattern features for extracting a plurality of function models for a plurality of processes. The program code on the medium would also be comprised of program code for inputting the dimensions of the plurality of pattern features after each one of the plurality of processes is performed on the wafer and program code for extracting a function model for each one of the plurality of processes based on the inputted dimensions of the plurality of pattern features. Furthermore, the program code on the medium would be comprised of program code for obtaining a correction model for each one of the plurality of processes, wherein the function model for each of the plurality of processes is used to extrapolate a pattern feature correction to achieve a desired feature dimension. Finally, the program code on the medium would be comprised of program code for reading a photo mask design pattern, program code for applying the correction model for each one of the plurality of processes to the photo mask design pattern successively, wherein a corrected photo mask design pattern is generated, and program code for generating a final set of mask data of the corrected photo mask design pattern that is generated.

Additional advantages of the embodiments will be set forth in part in the description which follows, and in part will be obvious from the description, or may be learned by practice of the invention. The advantages will be realized and attained by means of the elements and combinations particularly pointed out in the appended claims.

It is to be understood that both the foregoing general description and the following detailed description are exemplary and explanatory only and are not restrictive of the invention, as claimed.

The accompanying drawings, which are incorporated in and constitute a part of this specification, illustrate embodiments of the invention and together with the description, serve to explain the principles of the invention.

### BRIEF DESCRIPTION OF THE DRAWINGS

FIG. 1 depicts a diagram of the steps comprising a method of obtaining a corrected mask in accordance with various embodiments of the present invention.

FIG. 2 depicts a diagram of the steps comprising a method of obtaining a corrected mask in accordance with various embodiments of the present invention in which only the etch and print steps will be modeled.

FIG. 3 depicts a diagram of the steps comprising a method of obtaining a corrected mask in accordance with various embodiments of the present invention.

FIG. 4 depicts a diagram of the steps comprising a method of obtaining a corrected mask in accordance with various embodiments of the present invention in which only the etch and print steps will be modeled.

FIG. 5 depicts a diagram of the steps and results of a method of obtaining an OPC model in accordance with various embodiments of the present invention.

FIG. 6 depicts a diagram of the steps and results of a method of obtaining a final mask data set in accordance with various embodiments of the present invention.

### DESCRIPTION OF THE EMBODIMENTS

Reference will now be made in detail to the present embodiments, examples of which are illustrated in the accompanying drawings. Wherever possible, the same reference numbers will be used throughout the drawings to refer to the same or like parts.

Although reference is made herein to the use of the invention in the manufacture of ICs, it is to be understood that the invention has many other possible applications. For example, it may be employed in the manufacture of integrated optical systems, guidance and detection patterns for magnetic domain memories, liquid crystal display panels, thin-film magnetic heads, etc. Further, one of ordinary skill in the art will appreciate that, in the context of such alternative applications, any use of the terms “reticle”, “wafer”, and “die” could be considered as being interchangeable with terms such as “mask”, “substrate”, and “target portion”, respectively.

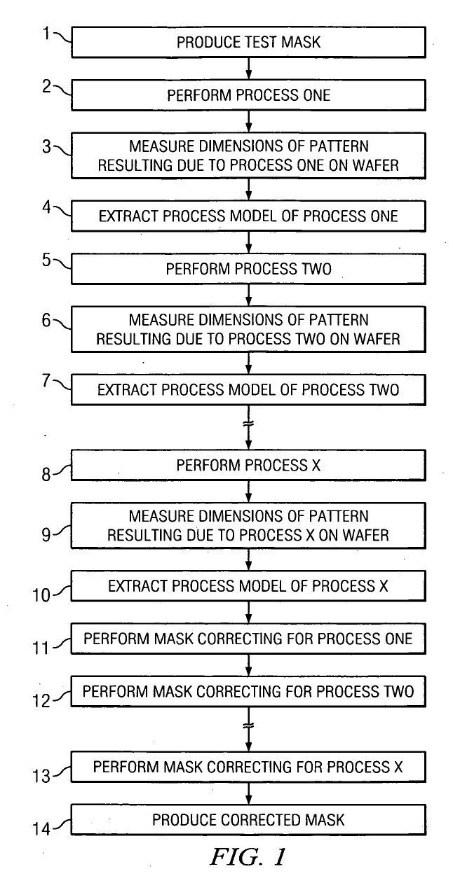

FIG. 1 illustrates the steps comprising a procedure for obtaining an OPC model and a corrected mask as the test mask is processed in accordance with an embodiment of the present invention.

First, at a test mask producing step, step 1, a test mask is produced. The test mask is a mask that functions as a mask for extracting a process model corresponding to the optical proximity effect correction. When the test mask is produced, an allowable range of an error of line width depending on pattern density is set in accordance with the manufacturing capabilities of a manufacturing facility. Thereafter, a mask producing condition is set so that the error of line width depending on coarse/dense pattern of the test mask is restricted in the allowable range.

The mask producing condition for which the test mask is produced can include a similar condition as a mask producing condition for which the error of line width depends on the pattern density of a corrected mask produced at step 14 can be restricted in the allowable range. In other words, the error of line width can be an intermediate value of the production error, depending on coarse/dense patterning.

Thereafter, the flow advances to a first manufacturing process, step 2. Thereafter, the flow advances to a transfer wafer measuring step, step 3. At step 3, the dimensions of the resulting pattern from the process performed in step 2 on the wafer are measured by CD-SEM or the like.

Thereafter, the flow advances to a first process model extracting step, step 4. At step 4, a function model of a second manufacturing process that uses a general purpose OPC simulator is extracted or obtained using the test mask dimensions and the transferred pattern dimension. Thus, a simulated transferred pattern is formed after the first process. Further, the simulated transferred pattern is formed in accordance with the process model extracted by the general-purpose OPC simulator. This step results in the simulated transferred pattern matching the measured result obtained at step 3.

Thereafter, the flow advances to the second manufacturing process, step 5. Thereafter, the flow advances to a transfer wafer measuring step, step 6. At step 6, the dimensions of the resulting pattern from the process performed in step 5 on the wafer are measured by CD-SEM or the like.

Thereafter, the flow advances to a second process model extracting step, step 7. At step 7, a function model of the second manufacturing process that uses a general-purpose OPC simulator is extracted or obtained using the first manufacturing process dimensions measured in step 3 and the transferred pattern dimension measured in step 6. Thus, the simulated transferred pattern is updated after the second process. Further, the simulated transferred pattern is formed in accordance with the process model extracted by the general-purpose OPC simulator. This step results in the simulated transferred pattern matching the measured result obtained at step 6.

The flow repeats the steps of performing a process step, measuring the dimensions of the resulting pattern, and extracting a version of the process step model as in steps 5, 6, 7 until the flow advances to a final process step, step 8, a measurement step, step 9, and a model extraction step, step 10.

Thereafter, the flow advances to a first mask correcting step, step 11. At step 11, a first corrected mask pattern in which the simulated transferred pattern matches a designed pattern is obtained. The first corrected mask pattern is obtained using the process model obtained at step 4 by the foregoing general-purpose simulator. As a result, mask CAD data for the mask to be produced is created.

Thereafter, the flow advances to a second mask correcting step, step 12. At step 12, a second corrected mask pattern in which the simulated transferred pattern matches the first corrected pattern is obtained using the process model obtained at step 7 by the foregoing general-purpose simulator. As a result, mask CAD data for the mask to be produced is created.

Thereafter, the flow advances to subsequent mask correcting steps until a final correcting step, step 12. At step 12, a final corrected mask pattern is obtained using the process model obtained at step 10 by the foregoing general-purpose simulator. The simulated resulting pattern in the final corrected mask pattern matches the previous corrected pattern. As a result, mask CAD data for the mask to be produced is created.

Thereafter, the flow advances to a corrected mask production step, step 14. At step 14, a corrected mask is produced in accordance with the final set of created mask CAD data.

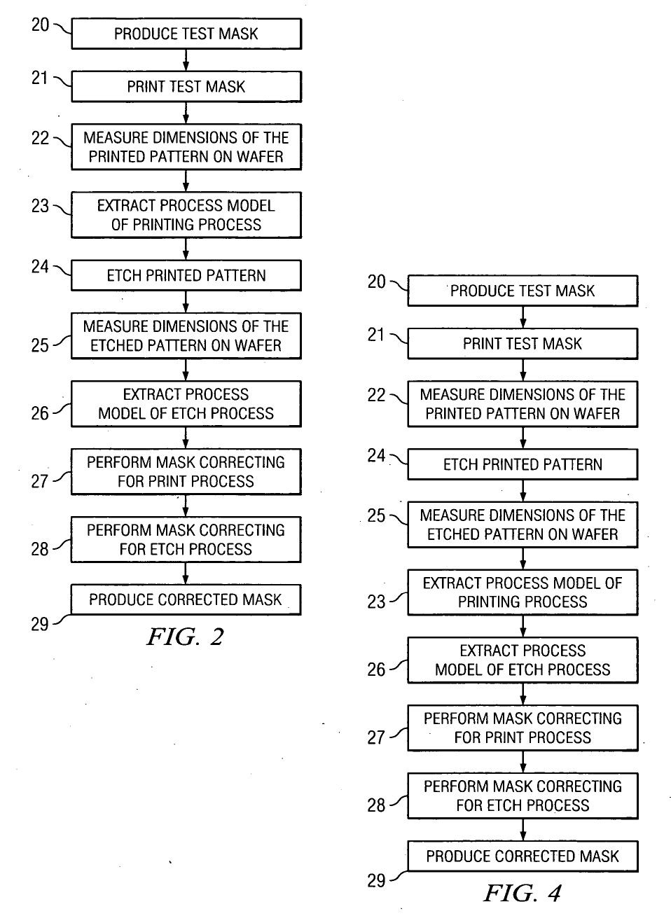

FIG. 2 illustrates the steps comprising a procedure for obtaining an OPC model and a corrected mask in accordance with an embodiment of the present invention. The steps shown in FIG. 2 comprise modeling steps for printing a pattern and etching a pattern.

First, a test mask is produced at test mask producing step 20. The test mask is a mask that can function as a mask for extracting a process model corresponding to the optical proximity effect correction. When the test mask is produced, an allowable range of an error of line width, which can depend on coarse/dense patterning, is set in accordance with the manufacturing capabilities of a manufacturing facility. Thereafter, a mask producing condition is set so that the error of line width depending on pattern density of the test mask is restricted in the allowable range. The test mask is produced in accordance with the mask producing condition.

The mask producing condition for which the test mask is produced can include a similar condition as a mask producing condition for which the error of line width depending on pattern density of a corrected mask produced at step 29 is restricted in the allowable range. In other words, the error of line width depending on coarse/dense patterning can be an intermediate value of the production error.

Thereafter, the flow advances to a printing or lithographic pattern transfer manufacturing process, step 21. Thereafter, the flow advances to a wafer measuring step, step 22. At step 22, the dimensions of the transferred pattern from the lithographic process performed in step 21 on the wafer are measured by CD-SEM or the like.

Thereafter, the flow advances to a lithographic process model extracting step, step 23. At step 23, a function model of the lithographic process, using a general-purpose OPC simulator, is extracted or obtained using the test-mask dimensions and the transferred pattern dimension. Thus, the simulated transferred pattern after the lithographic step obtained in accordance with the process model extracted by the general-purpose OPC simulator results in the simulated transferred pattern matching to the measured result obtained at step 22.

Thereafter, the flow advances to an etch manufacturing process, step 24. Thereafter, the flow advances to a transfer wafer measuring step, step 25. At step 25, the dimensions of the resulting pattern from the etch process performed in step 24 on the wafer are measured by CD-SEM or the like.

Thereafter, the flow advances to an etch process model extracting step, step 26. At step 26, a function model of the etch process, using a general-purpose OPC simulator, is extracted or obtained. This can be done using the transferred pattern dimensions obtained in step 22 and the resulting pattern dimension obtained in step 25. Thus, the simulated resulting pattern of the wafer after the etch step, obtained in accordance with the process model extracted by the general-purpose OPC simulator, results in the simulated transferred pattern matching the measured result obtained at step 22.

Thereafter, the flow advances to a first mask correcting step, step 27. At step 27, a first correction is made to the design pattern by the lithographic OPC process model obtained at step 23. As such, the simulated resulting pattern after a lithographic process matches a designed pattern.

Thereafter, the flow advances to a second mask correcting step, step 28. At step 28, a second correction is made by the etch OPC process model obtained at step 26. In this case, the simulated resulting pattern after an etch process can match a designed pattern. As a result, mask CAD data for the mask to be produced is created, incorporating the lithographic and etch process corrections.

Thereafter, the flow advances to a corrected mask producing step, step 29. At step 29, a corrected mask is produced in accordance with the final set of created mask CAD data at step 28.

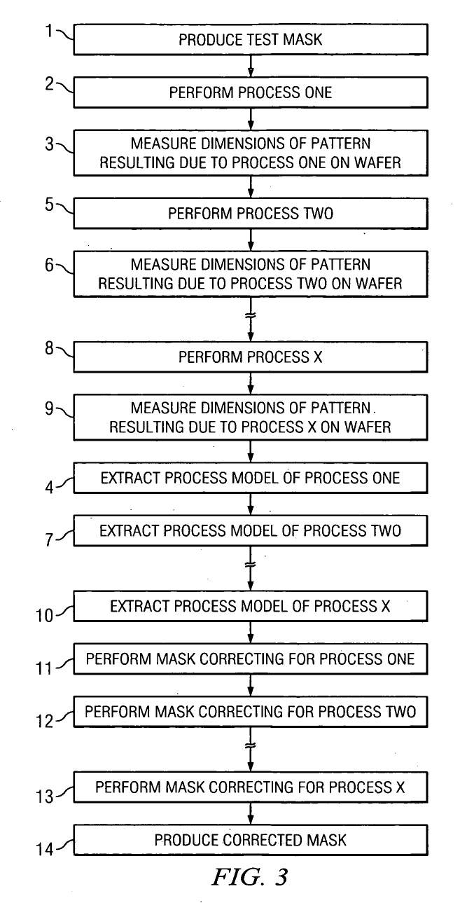

According to various embodiments of the invention, the process OPC models will not be extracted until all processing is completed, rather than concurrently with processing, as shown in FIGS. 3 and 4. The process flow shown in FIG. 3 is similar to the process flow shown in FIG. 1, with the exception of when the process models are extracted. In such embodiments, rather than having a process flow that immediately extracts a model for each process after initial process steps, such as process steps 2, 5, and 8 and their respective measuring steps 3, 6, and 9, all process steps and measuring steps can be completed before any extraction is completed. As such, after the last measuring step 9, the flow can advance through the model extraction steps 4, 7, and 10 as previously discussed. The flow can then advance to the correction steps for each process 11, 12, and 13 and then finally advance to the step in which the obtained mask CAD data is used to produce a corrected mask 14.

Similarly, FIG. 4 illustrates the steps comprising the procedure for obtaining an OPC model and a corrected mask in accordance with an embodiment of the present invention. The method of FIG. 4 comprises modeling the steps of printing a pattern and etching a pattern. However, in certain embodiments, the process OPC models will not be extracted until all processing is completed, rather than concurrently.

The process flow shown in FIG. 4 is similar to the process flow shown in FIG. 2, with the exception of when the process models are extracted. In this embodiment, rather than having a process flow that immediately extracts a model for the lithographic process step 21 and the etch step 24 and their respective measuring steps 22 and 25, all process steps and measuring steps can be completed before any extraction is completed. Therefore, after the last measuring step 25, the flow can be advanced through the model extraction steps 23 and 26, as previously discussed. The flow will then advance to the correction steps for each process 27 and 28 and then finally advance to the step in which the obtained mask CAD data is used to produce a corrected mask 29.

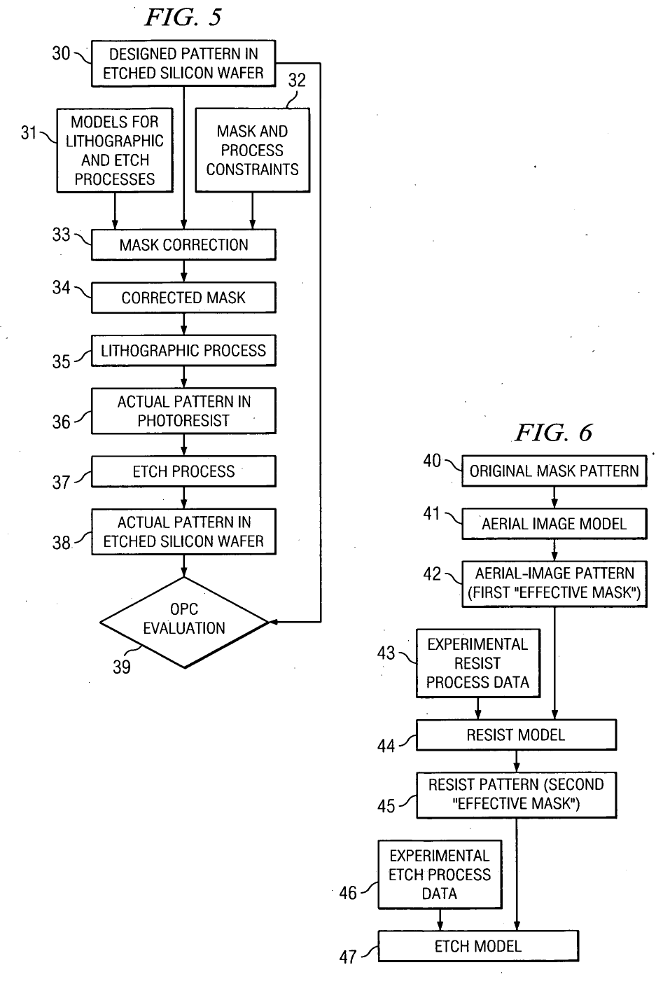

In other embodiments, OPC correction can be limited by the mask producing process or the wafer manufacturing process, as shown, for example, in FIG. 5. In some instances, the resolution of the mask producing may be limited and the desired corrections may not be achieved or the required amount of correction may result in merging of features. In other instances, the wafer manufacturing process may also result in features improperly imaged on the wafer. Other process or mask production limitations may also be required to be included in any OPC model. To account for such variation, the flow can be altered. For example, a design pattern 30 can be provided for evaluation. OPC process models 31, such as for etch and lithographic processes, are applied to the design. At this point, the amount of correction required may be limited by the known mask and process constraints 32.

The type of correction shown in FIG. 5 may also be used to perfect the OPC correction on a mask. In some embodiments, it may be desirable to derive the model iteratively or to evaluate device performance relative to the amount of OPC correction. In such embodiments, after a mask is corrected 33, the produced mask is put through the device process flow. In some embodiments, the model may comprise a lithographic process 35, in which a pattern is formed in photoresist 36, followed by an etch process 37, which will leave an actual pattern on the wafer 38. In other embodiments, there may also be many more process steps required to form an actual pattern on the wafer 38. Once an actual pattern is formed, further refinement of the OPC model may be completed by comparing the actual pattern to the initial designed pattern in an evaluation step 39. At this point, a decision as to further refinements of the OPC models 31 and other process limitations 32 can be made before producing any further mask.

In some embodiments, a computer program may be used to model processes and ultimately create the final mask. In such embodiments, a program code may be designed using a flow as shown in FIG. 6. For example, program code that allows an original mask pattern to be inputted is executed 40. This is followed by program code for executing an optical model that simulates the exposure conditions for the desired lithographic manufacturing process 41. Such models are well understood by those of ordinary skill in the art. This model can provide a simulated expected pattern 42. Additional program code that allows actual or experimental lithographic data to be inputted 43 can also be used. At this point, there is program code that, based on the simulated expected pattern and the resulting pattern, extracts a resist process model 44. Also included can be additional program code to input the resulting resist pattern 43 and the resulting or experimental etch pattern 46. This additional program code can be integrated into program code that extracts a model for the etch process 47. In other embodiments, the program code may be designed to extract models for any number of processes.

While the invention has been illustrated with respect to one or more implementations, alterations and/or modifications can be made to the illustrated examples without departing from the spirit and scope of the appended claims. In addition, while a particular feature of the invention may have been disclosed with respect to only one of several implementations, such a feature may be combined with one or more other features of the other implementations as may be desired and advantageous for any given or particular function. Furthermore, to the extent that the terms “including”, “includes”, “having”, “has”, “with”, or variants thereof are used in either the detailed description and the claims, such terms are intended to be inclusive in a manner similar to the term “comprising.”

Other embodiments of the invention will be apparent to those skilled in the art from consideration of the specification and practice of the invention disclosed herein. It is intended that the specification and examples be considered as exemplary only, with a true scope and spirit of the invention being indicated by the following claims.

What is claimed is:

1. A method for manufacturing a corrected photo mask using an optical proximity effect correction method, the method comprising:
producing a test mask that provides a mask pattern for extracting a plurality of function models of a plurality of processes for the optical proximity effect correction method;
transferring the mask pattern to a wafer by executing the plurality of processes, wherein each one of the plurality of processes forms a resulting pattern on the wafer;
measuring the dimensions of the resulting pattern on the wafer after each one of the plurality of processes is executed;
obtaining a function model for each one of the plurality of processes executed in which the dimensions of a simulated resulting pattern match the dimensions of the resulting pattern on the wafer after each one of the plurality of processes is executed;
providing a photo mask design pattern;
obtaining a mask pattern of which a simulated transferred pattern matches the photo mask design pattern by applying the function model for each one of the plurality of processes sequentially and creating mask data in accordance with the simulated transferred pattern; and
producing a corrected photo mask in accordance with the created mask data.

2. The method of claim 1, wherein the step of transferring to the wafer comprises:
printing the mask pattern onto the wafer using the test mask; and
etching the mask pattern into the wafer.

3. The method of claim 2, wherein the step of printing the mask pattern comprises:
exposing a photoresist layer on the wafer to a light source through the test mask; and
developing the photoresist layer to form the mask pattern on the wafer.

4. The method of claim 2, wherein the step of etching the resulting pattern further comprises a plurality of etch processes.

5. The method of claim 1, wherein the step of obtaining a function model for one of the plurality of processes comprises:
inputting the dimensions of the resulting pattern before the one of the plurality of processes is executed; and
inputting the dimensions of the resulting pattern after the one of the plurality of processes is executed.

6. The method of claim 1, wherein the plurality of function models corresponding to the plurality of processes are extracted for applying the optical proximity effect correction method.

7. The method of claim 1, wherein the plurality of function models corresponding to the plurality of processes are extracted for obtaining the optical proximity effect correction method.

8. A method for manufacturing a semiconductor device using a corrected photo mask using an optical proximity effect correction method, the method comprising:
producing a test mask that provides a mask pattern for extracting a plurality of function models of a plurality of processes for applying the optical proximity effect correction method;
transferring the mask pattern to a wafer by executing the plurality of processes, wherein each one of the plurality of processes forms a resulting pattern on the wafer;
measuring the dimensions of the resulting pattern on the wafer after each one of the plurality of processes is executed;
obtaining a function model for each one of the plurality of processes executed in which the dimensions of a simulated resulting pattern match the dimensions of the resulting pattern on the wafer after each one of the plurality of processes is executed;
providing a photo mask design pattern;
obtaining a mask pattern of which a simulated transferred pattern matches the photo mask design pattern by applying the function model for each one of the plurality of processes sequentially and creating mask data in accordance with the simulated transferred pattern;
producing a corrected photo mask in accordance with the created mask data; and
transferring a corrected mask pattern to a wafer by executing the plurality of processes, wherein each one of the plurality of processes forms a resulting corrected pattern on the wafer.

9. The method of claim 8, wherein the step of transferring the mask pattern to the wafer and the step of transferring the corrected mask pattern to the wafer comprise:
printing the mask pattern onto the wafer using the test mask; and
etching the mask pattern into the wafer.

10. The method of claim 9, wherein the step of printing the mask pattern comprises:
exposing a photoresist layer on the wafer to a light source through the test; and
developing the photoresist layer to form the mask pattern on the wafer.

11. The method of claim 9, wherein the step of etching the resulting pattern comprises of a plurality of etch processes.

12. The method of claim 8, wherein the step of obtaining a function model for one of the plurality of processes a set of data inputs further comprises:
inputting the dimensions of the resulting pattern before the one of the plurality of processes is executed; and
inputting the dimensions of the resulting pattern after the one of the plurality of processes is executed.

13. A method for obtaining an optical proximity effect correction model, the method comprising:
producing a test mask that provides a mask pattern for extracting a plurality of function models of a plurality of processes for obtaining the optical proximity effect correction model;
transferring the mask pattern to a wafer by executing the plurality of processes, wherein each one of the plurality of processes forms a resulting pattern on the wafer;
measuring the dimensions of the resulting pattern on the wafer after each one of the plurality of processes is executed; and
obtaining a function model for each one of the plurality of processes executed in which the dimensions of a simulated resulting pattern match the dimensions of the resulting pattern on the wafer after each one of the plurality of processes is executed.

14. The method of claim 13, wherein the step of transferring to the wafer comprises:
printing the mask pattern onto the wafer using the test mask; and
etching the mask pattern into the wafer.

15. The method of claim 14, wherein the step of printing the mask pattern comprises:
exposing a photoresist layer on the wafer to a light source through the test mask; and
developing the photoresist layer to form the mask pattern on the wafer.

16. The method of claim 14, wherein the step of etching the resulting pattern comprises a plurality of etch processes.

17. The method of claim 13, wherein the step of obtaining a function model for one of the plurality of processes a set of data inputs further comprises:
inputting the dimensions of the resulting pattern before the one of the plurality of processes is executed; and
inputting the dimensions of the resulting pattern after the one of the plurality of processes is executed.

18. A integrated circuit device formed according to the method comprising the steps of:
producing a test mask that provides a mask pattern for extracting a plurality of function models of a plurality of processes;
transferring the mask pattern to a wafer by executing the plurality of processes, wherein each one of the plurality of processes forms a resulting pattern on the wafer;
measuring the dimensions of the resulting pattern on the wafer after each one of the plurality of processes is executed;
obtaining a function model for each one of the plurality of processes executed in which the dimensions of a simulated resulting pattern match the dimensions of the resulting pattern on the wafer after each one of the plurality of processes is executed;
providing a photo mask design pattern;
obtaining a mask pattern of which a simulated transferred pattern matches the photo mask design pattern by applying the function model for each one of the plurality of processes sequentially and creating mask data in accordance with the simulated transferred pattern;
producing a corrected photo mask in accordance with the created mask data; and
transferring a corrected mask pattern to a wafer by executing the plurality of processes sequentially, wherein each one of the plurality of processes forms a resulting corrected pattern on the wafer.

19. The device of claim 18, wherein the step of transferring to the wafer comprises:
printing the mask pattern onto the wafer using the test mask; and
etching the mask pattern into the wafer.

20. The device of claim 19, wherein the step of printing the mask pattern comprises:
exposing a photoresist layer on the wafer to a light source through the test mask; and
developing the photoresist layer to form the mask pattern on the wafer.

21. The device of claim 19, wherein the step of etching the resulting pattern comprises a plurality of etch processes.

22. The device of claim 18, wherein the step of obtaining a function model for one of the plurality of processes a set of data inputs further comprises:
inputting the dimensions of the resulting pattern before the one of the plurality of processes is executed; and
inputting the dimensions of the resulting pattern after the one of the plurality of processes is executed.

23. A corrected photo mask formed according to the method comprising the steps of:
producing a test mask that provides a mask pattern for extracting a plurality of function models of a plurality of processes;
transferring the mask pattern to a wafer by executing the plurality of processes, wherein each one of the plurality of processes forms a resulting pattern on the wafer;
measuring the dimensions of the resulting pattern on the wafer after each one of the plurality of processes is executed;
obtaining a function model for each one of the plurality of processes executed in which the dimensions of a simulated resulting pattern match the dimensions of the resulting pattern on the wafer after each one of the plurality of processes is executed;
providing a photo mask design pattern;
obtaining a mask pattern of which a simulated transferred pattern matches the photo mask design pattern by applying the function model for each one of the plurality of processes sequentially and creating mask data in accordance with the simulated transferred pattern; and
producing a corrected photo mask in accordance with the created mask data.

24. The photo mask of claim 23, wherein the step of transferring to the wafer comprises:
printing the mask pattern onto the wafer using the test mask; and
etching the mask pattern into the wafer.

25. The photomask of claim 24, wherein the step of printing the mask pattern comprises:
exposing a photoresist layer on the wafer to a light source through the test mask; and
developing the photoresist layer to form the mask pattern on the wafer.

26. The method of claim 24, wherein the step of etching the resulting pattern comprises a plurality of etch processes.

27. The method of claim 23, wherein the step of obtaining a function model for one of the plurality of processes a set of data inputs further comprises:
inputting the dimensions of the resulting pattern before the one of the plurality of processes is executed; and
inputting the dimensions of the resulting pattern after the one of the plurality of processes is executed.

28. A computer readable medium containing program code that configures a processor to obtain a model for correcting a mask layout using an optical proximity correction method to account for a plurality of processes to be performed on a wafer, comprising:
program code for reading a test mask pattern comprising a plurality of pattern features for extracting a plurality of function models for a plurality of processes;
program code for inputting the dimensions of the plurality of pattern features after each one of the plurality of processes is performed on the wafer;
program code for extracting a function model for each one of the plurality of processes based on the inputted dimensions of the plurality of pattern features; and
program code for obtaining a correction model for each one of the plurality of processes, wherein the function model for each of the plurality of processes is used to extrapolate a pattern feature correction to achieve a desired feature dimension.

29. A computer readable medium containing program code that configures a processor to correct a mask layout using an optical proximity correction method which accounts for a plurality of processes to be performed on a wafer, comprising:
program code for reading a test mask pattern comprising a plurality of pattern features for extracting a plurality of function models for a plurality of processes;
program code for inputting the dimensions of the plurality of pattern features after each one of the plurality of processes is performed on the wafer;
program code for extracting a function model for each one of the plurality of processes based on the inputted dimensions of the plurality of pattern features;
program code for obtaining a correction model for each one of the plurality of processes, wherein the function model for each of the plurality of processes is used to extrapolate a pattern feature correction to achieve a desired feature dimension; program code for reading a photo mask design pattern;
program code for applying the correction model for each one of the plurality of processes to the photo mask design pattern successively, wherein a corrected photo mask design pattern is generated; and
program code for generating a final set of mask data of the corrected photo mask design pattern that is generated.
